(19) United States
(12) Patent Application Publication
(10) Pub. No.: US 2024/0190018 A1
(43) Pub. Date: Jun. 13, 2024

(54) TRANSFER ROBOT SYSTEM AND THE TRANSFER ROBOT SYSTEM DRIVING METHOD

(71) Applicant: SEMES CO., LTD., Cheonan-si (KR)

(72) Inventor: Jung Woo KIM, Cheonan-si (KR)

(73) Assignee: SEMES CO., LTD., Cheonan-si (KR)

(21) Appl. No.: 18/333,430

(22) Filed: Jun. 12, 2023

(30) Foreign Application Priority Data
Dec. 13, 2022 (KR) 10-2022-0173543

(51) Int. Cl. B25J 11/00; B25J 5/00; B25J 9/16; B25J 13/08

(52) U.S. Cl. CPC B25J 11/0095; B25J 5/007; B25J 9/1697; B25J 13/087

(57) ABSTRACT

Embodiments of the inventive concept provide a transfer robot system and a transfer robot system driving method collecting a state information of a semiconductor manufacturing facility even without using a regular inspection method of the semiconductor manufacturing facility by an operator, so an inspection time and a replacement time may be known. The inventive concept provides a transfer robot system. The transfer robot system includes: an autonomous driving apparatus which transfers an article which is required by semiconductor manufacturing facilities and which collects a state information of a semiconductor manufacturing facility by autonomously driving within a space at which the semiconductor manufacturing facilities are installed; and a state monitoring unit connected with the autonomous driving apparatus to continuously be input with the state information of the semiconductor manufacturing facilities and for monitoring a change value of the state information.

### CROSS-REFERENCE TO RELATED APPLICATIONS

A claim for priority under 35 U.S.C. § 119 is made to Korean Patent Application No. 10-2022-0173543 filed on Dec. 13, 2022, in the Korean Intellectual Property Office, the entire contents of which are hereby incorporated by reference.

### BACKGROUND

Embodiments of the inventive concept described herein relate to a transfer robot system and a transfer robot system driving method, more specifically, a transfer robot system and a transfer robot system driving method for monitoring a semiconductor manufacturing facility.

Various semiconductor manufacturing facilities for semiconductor manufacturing are installed in a semiconductor manufacturing line, and these semiconductor manufacturing facilities repeatedly perform manufacturing processes.

Therefore, the semiconductor manufacturing facilities are regularly inspected according to a planned work schedule.

In particular, facilities which have performed for a long-term require continuous management because a performance degradation occurs due to a wearing down between parts during an operation, or a damaging of parts due to a degrading.

In this way, an operator must continuously inspect the parts using the inspection equipment to check if the parts are worn down or degraded.

However, in conventional semiconductor manufacturing facilities, the wearing down or the degrading of parts of the semiconductor manufacturing facilities may not be detected if the operator neglect an inspection, checks visually, or does not understand how to use the inspection equipment.

If the semiconductor manufacturing facility shuts down, a thorough inspection is carried out to analyze a cause of failure. During the thorough inspection, the semiconductor manufacturing facility has to be stopped, resulting in a cost loss.

### SUMMARY

Embodiments of the inventive concept provide a transfer robot system and a transfer robot system driving method collecting a state information of a semiconductor manufacturing facility even without using a regular inspection method of the semiconductor manufacturing facility by an operator, so an inspection time and a replacement time may be known.

The technical objectives of the inventive concept are not limited to the above-mentioned ones, and the other unmentioned technical objects will become apparent to those skilled in the art from the following description.

The inventive concept provides a transfer robot system. The transfer robot system includes an autonomous driving apparatus which transfers an article which is required by semiconductor manufacturing facilities and which collects a state information of a semiconductor manufacturing facility by autonomously driving within a space at which the semiconductor manufacturing facilities are installed; and a state monitoring unit connected with the autonomous driving apparatus to continuously be input with the state information of the semiconductor manufacturing facilities and for monitoring a change value of the state information.

In an embodiment, the autonomous driving apparatus consists of at least one among an OHT and a mobile robot.

In an embodiment, the autonomous driving apparatus further includes a proximity sensor which generates a facility scan information about the semiconductor manufacturing facility into the state information.

In an embodiment, the autonomous driving apparatus further includes a camera sensor which generates a facility image information of an image of the semiconductor manufacturing facility into the state information.

In an embodiment, the autonomous driving apparatus further includes a sound detection sensor which generates a facility sound information of a sound of the semiconductor manufacturing facility into the state information.

In an embodiment, the autonomous driving apparatus further includes a vibration detection sensor which generates a facility vibration information of a sound of the semiconductor manufacturing facility into the state information.

In an embodiment, the autonomous driving apparatus further includes a temperature detection sensor which generates a facility temperature information of a temperature of the semiconductor manufacturing facility into the state information.

In an embodiment, the state monitoring unit further includes an inspection information storage unit which stores a facility name of the semiconductor manufacturing facility and an inspection time every set cycle, together with the state information.

In an embodiment, the state monitoring unit further includes an abnormality detection unit for determining whether the state information has a change from a pre-stored value, if the state information is input in communication with the inspection information storage unit.

In an embodiment, the state monitoring unit further includes a facility life prediction unit for monitoring how much a change rate of a intensity or a range of the state information increases during a predetermined period, in communication with the abnormality detection unit.

The inventive concept provides a transfer robot system driving method. The transfer robot system driving method includes autonomously driving an autonomous driving apparatus; acquiring a state information of a semiconductor manufacturing facility by the autonomous driving apparatus; storing the state information by the monitoring unit; and detecting whether there is a change by comparing with a state information which is pre-stored if inputting the state information.

In an embodiment, the transfer robot system driving method further includes generating an alarm information divided into grades according to a change rate of a intensity or a range of the state information if a change occurs in the state information.

In an embodiment, the alarm information is generated as a normal grade if a change rate of the state information is the same or below a lower standard value, is generated as an inspection grade if the change rate of the state information does not exceed a critical value which is the same or above the lower standard value, and is generated as a replacement grade if the change rate of the state information exceeds the critical value.

In an embodiment, the transfer robot system driving method further includes a life prediction unit for predicting a failure time of the semiconductor manufacturing facility by monitoring how much a change rate of the state information has increased during a set period.

In an embodiment, the state information is a facility scan information with respect to a shape of the semiconductor manufacturing facility.

In an embodiment, the state information is a facility scan information with respect to an image of the semiconductor manufacturing facility.

In an embodiment, the state information is a facility sound information with respect to a sound of the semiconductor manufacturing facility.

In an embodiment, the state information is a facility vibration information with respect to a vibration of the semiconductor manufacturing facility.

In an embodiment, the state information is a facility temperature information with respect to a temperature of the semiconductor manufacturing facility.

The inventive concept provides a transfer robot system. The transfer robot system includes an autonomous driving apparatus which transfers an article to semiconductor manufacturing facilities and which collects a state information of a semiconductor manufacturing facility by autonomously driving within a space at which the semiconductor manufacturing facilities are installed, and which is configured of at least one among an OHT and a mobile robot; and a state monitoring unit connected with the autonomous driving apparatus to continuously be input with the state information of the semiconductor manufacturing facilities and for monitoring a change value of the state information, and wherein the transfer robot system further comprises a proximity sensor which generates a facility scan information a shape of the semiconductor manufacturing facility into the state information; a camera sensor which generates a facility image information of an image of the semiconductor manufacturing facility into the state information; a sound detection sensor which generates a facility sound information of a sound of the semiconductor manufacturing facility into the state information; a vibration detection sensor which generates a facility vibration information of a sound of the semiconductor manufacturing facility into the state information; and a temperature detection sensor which generates a facility temperature information of a temperature of the semiconductor manufacturing facility into the state information, and wherein the transfer robot system further comprises an inspection information storage unit which stores a facility name of the semiconductor manufacturing facility and an inspection time every set cycle, together with the state information; an abnormality detection unit for determining whether the state information has a change from a pre-stored value, if the state information is input in communication with the inspection information storage unit; and a facility life prediction unit for monitoring how much a change rate of a intensity or a range of the state information increases during a predetermined period, in communication with the abnormality detection unit.

According to an embodiment of the inventive concept, a state information of a semiconductor manufacturing facility is collected so an inspection time and a replacement time may be known even without using a regular inspection method of the semiconductor manufacturing facility by an operator.

The effects of the inventive concept are not limited to the above-mentioned ones, and the other unmentioned effects will become apparent to those skilled in the art from the following description.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIG. 1 is a plan view of a transfer robot system according to an embodiment of the inventive concept.

FIG. 2 is an enlarged side block view of a semiconductor manufacturing facility of the transfer robot system shown in FIG. 1.

FIG. 3 is a block view of electronic detailed configurations of an OHT shown in FIG. 2.

FIG. 4 is a block view of electronic detailed configurations of a mobile robot shown in FIG. 2.

FIG. 5 is a block view of electronic detailed configurations of a state monitoring unit shown in FIG. 2.

FIG. 6 is a flowchart of a transfer robot system driving method according to an embodiment of the inventive concept.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., +10%).

When the terms “about” or “substantially” are used in connection with a numerical value, it should be understood that the associated numerical value includes a manufacturing or operational tolerance (e.g., +10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

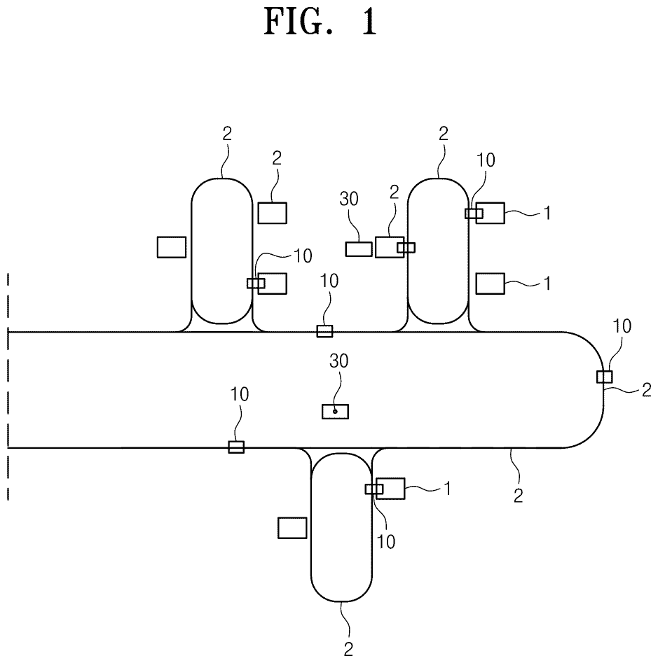

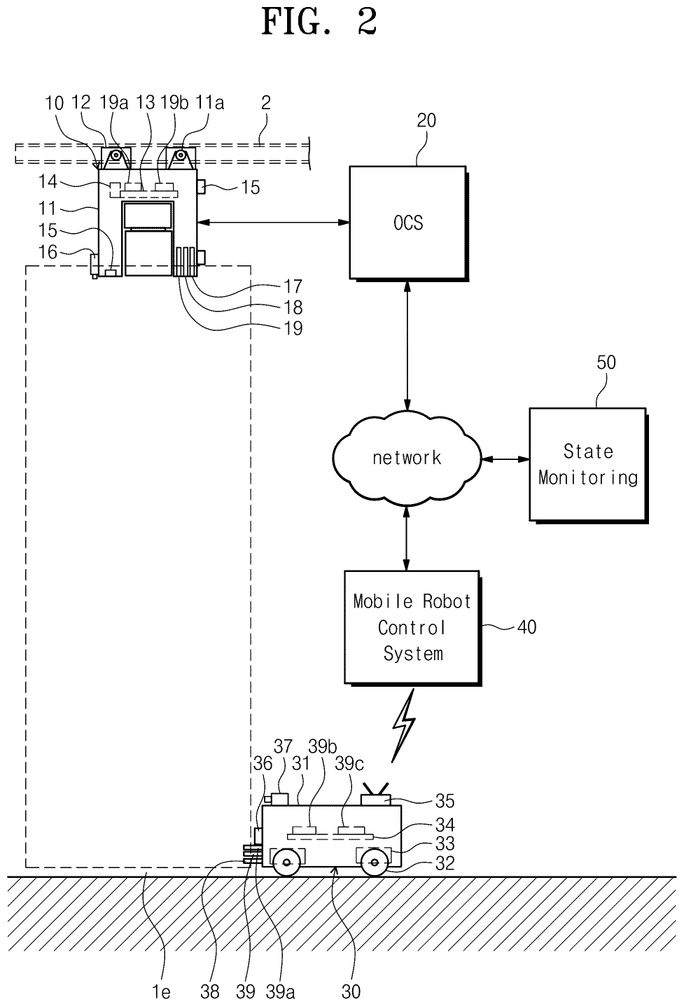

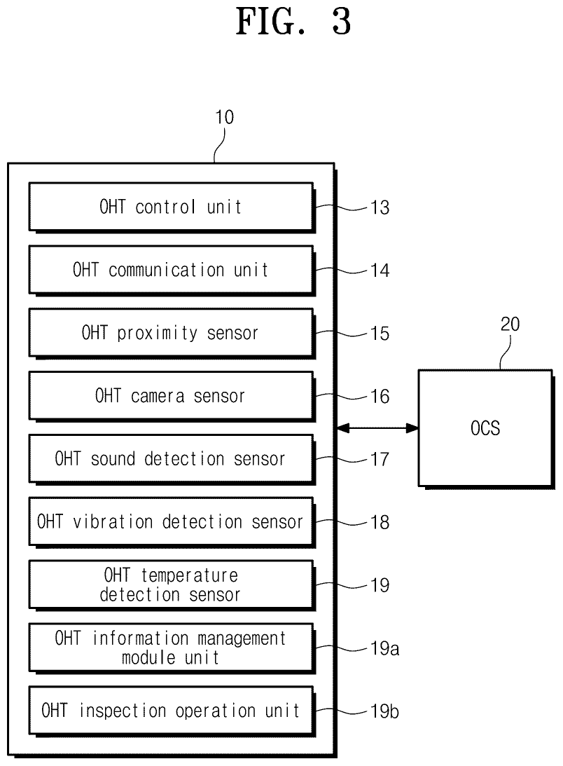

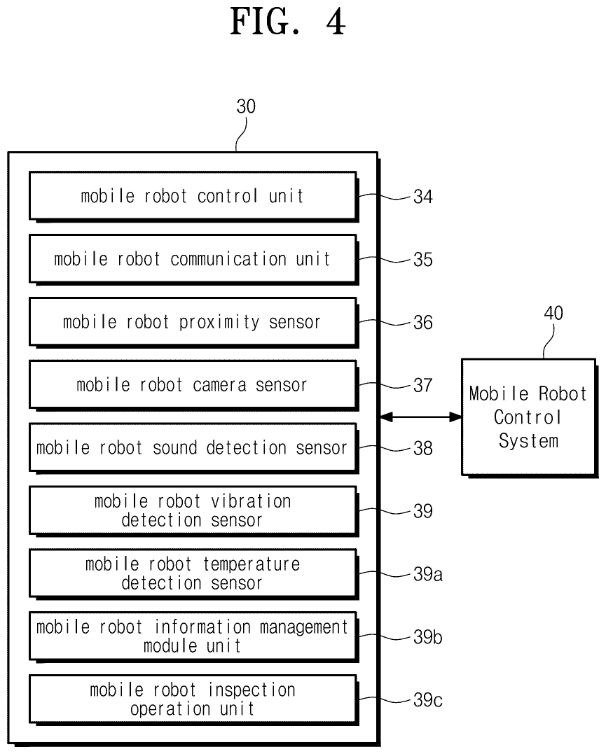

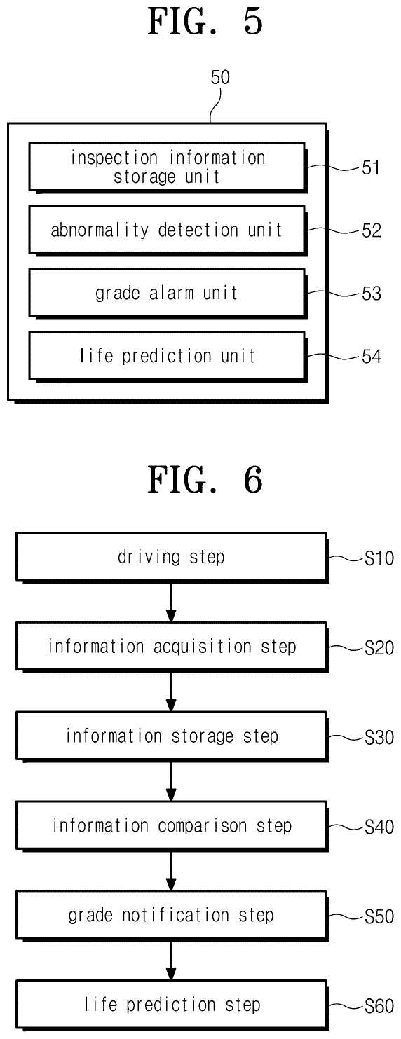

FIG. 1 is a plan view of a transfer robot system according to an embodiment of the inventive concept. FIG. 2 is an enlarged side block view of a semiconductor manufacturing facility of the transfer robot system shown in FIG. 1. FIG. 3 is a block view of electronic detailed configurations of an OHT shown in FIG. 2. FIG. 4 is a block view of electronic detailed configurations of a mobile robot shown in FIG. 2. FIG. 5 is a block view of electronic detailed configurations of a state monitoring unit shown in FIG. 2.

As shown in FIG. 1 to FIG. 5, the transfer robot system according to an embodiment of the inventive concept includes an OHT 10, an OCS 20, a mobile robot 30, a mobile robot control system 40, and a state monitoring unit 50.

The OHT 10 is an autonomous driving apparatus which automatically transfers a FOUP (Front Open Unified Pod), which is a sealed wafer container for storing and transferring wafers, while autonomously driving on a rail 2 installed in a top space of a semiconductor manufacturing facility 1. In this case, the OHT 10 receives an article scheduling information on an origin information, a destination information, and a loading article information which is to be loaded in connection with an OCS 20, automatically transfers an article to the rail 2 according to the article scheduling information, and stores and collects a state information with respect to each semiconductor manufacturing facility 1 which is a facility scan information, a facility sound information, a facility vibration information, and a facility temperature information.

In this case, the rail 2 of the path operated by the OHT 10 is installed in the top space spaced apart upwardly from the ground. Accordingly, the OHT 10 autonomously drives in a state in which a driving path does not overlap the mobile robot 30.

In this embodiment, the OHT 10 includes an OHT main body 11, an OHT driving unit 12, an OHT control unit 13, an OHT communication unit 14, an OHT proximity sensor 15, an OHT camera sensor 16, an OHT sound detection sensor, an OHT vibration detection sensor 18, an OHT temperature detection sensor 19, an OHT information management module unit 19a, and an OHT inspection operation unit 19b etc.

The OHT main body 11 provides a region at which the OHT driving unit 12, the OHT control unit 13, the OHT communication unit 14, the OHT proximity sensor 15, the OHT camera sensor 16, the OHT sound detection sensor 17, the OHT vibration detection sensor 18, the OHT temperature detection sensor 19, the OHT information management module unit 19a and the OHT inspection operation unit 19b are combined to, and is formed in a structure of various forms which transfers, loads and unloads the article on the FOUP within the semiconductor manufacturing facility 1. In addition, a driving roller 11a is formed on above the OHT main body 11. In this case, the driving roller 11a is installed on the rail 2 installed in the semiconductor manufacturing facility 1 factory, is coupled to a motor shaft of the OHT driving unit 12 coupled to the OHT main body 11, and moves the OHT main body 11 on a path of the rail 2 if a driving motor (not shown) moves.

The OHT driving unit 12 includes a motor (not shown) and a motor driving circuit (not shown), and the OHT main body 11 is driven on an autonomous driving path by receiving a control command according to an autonomous driving command of the OHT control unit 13 and driving the driving roller 11a connected to the motor.

The OHT control unit 13 is a control apparatus which controls the OHT driving unit 12 according to a preset program command, and controls the OHT driving unit 12 to autonomously drive through an autonomous driving algorithm while collision avoidance driving on a driving path of a pre-stored map for the OHT 10. In addition, the OHT control unit 13 communicates with the OCS 20 to receive an origin information, a destination information, and an article information, and transmits a command to the OHT driving unit 12 to transport the article while autonomously driving based on the input origin information, destination information and article information. In this case, the map for the OHT 10 is formed as image information with grid coordinate values for each pixel, and an information of the rail 2 which is a driving path is formed in the form of an image with grid coordinate values in the form of rails.

The OHT communication unit 14 is an apparatus which communicates with the OCS 20, and uses short-range communication such as a wireless LAN (Wifi), a short-range mesh network (N:N, Ad-hoc), a Bluetooth, a Zigbee, and an IrDA, or uses long-range communication if necessary. The OHT communication unit 14 transmits and receives an origin information, a destination information, and an article information from the OCS 20 to the OHT control unit 13, and transmits a position information and various status information of the OHT control unit 13 to the OCS 20. In addition, the OHT communication unit 14 transmits a facility scan information, a facility image information, a facility sound information, a facility vibration information, and a facility temperature information to the OCS 20 in conjunction with the OHT information management module unit 19a.

The OHT proximity sensor 15 is a sensor which detects obstacles in the autonomous driving path on the rail 2 through a distance detection, consisting of a laser distance detection sensor such as a lidar sensor and, if necessary, an ultrasonic displacement sensor or a light displacement sensor. Here, if detecting an obstacle, the OHT proximity sensor 15 transmits a collision warning information to the OHT control unit 13, and the OHT control unit 13 which has received the collision warning information modifies a driving path to a destination set to avoid the obstacle and drives autonomously.

In addition, the OHT proximity sensor 15 measures the semiconductor manufacturing facility 1 to generate the facility scan information by scanning an outer shape of the semiconductor manufacturing facility 1, and transmits the generated facility scan information to the OHT information management module unit 19a. Here, the facility scan information is an information obtained by forming the semiconductor manufacturing facility 1 on a three-dimensional coordinate through a distance value for each region of the OHT proximity sensor 15. In this case, the facility scan information may be formed as an image information having a grid coordinate value for each pixel, and a pixel information of the pixel may be set differently according to a sensed distance value of a 2D region to implement a 3D shape information.

The OHT camera sensor 16 consists of a 2D camera or a 3D sensing camera, and is installed in the OHT main body 11. The OHT camera sensor 16 acquires the facility image information by imaging the semiconductor manufacturing facility 1 if the OHT 10 moves, and transmits an acquired facility image information to the OHT information management module unit 19a.

The OHT sound detection sensor 17 is composed of a sensor which converts an analog sound into an electronic sound signal, such as a microphone, and is installed in the OHT main body 11. The OHT sound detection sensor 17 receives a facility sound information generated if the semiconductor manufacturing facility 1 is driven and transmits it to the OHT information management module unit 19a.

The OHT vibration detection sensor 18 is composed of a sensor capable of sensing a vibration like an acceleration sensor, and is installed in the OHT main body 11. The OHT vibration detection sensor 18 receives a facility vibration information generated if the semiconductor manufacturing facility 1 is driven and transmits it to the OHT information management module unit 19a.

The OHT temperature detection sensor 19 consists of a sensor capable of sensing a temperature, such as a thermocouple sensor or an infrared sensor, and is installed in the OHT main body 11. The OHT temperature detection sensor 19 measures a facility temperature information if the semiconductor manufacturing facility 1 is driven, and transmits the measured temperature information to the OHT information management module unit 19a.

Here, the facility scan information, the facility image information, the facility sound information, the facility vibration information, and the facility temperature information may be obtained in a state of entering the semiconductor manufacturing facility 1 among specific positions of the OHT 10 map which is pre-stored within the OHT 10.

The OHT information management module unit 19a records and manages the facility scan information, the facility image information, the facility sound information, the facility vibration information, and the facility temperature information, which are a state information for each of the semiconductor manufacturing facilities 1. The OHT information management module unit 19a receives and stores the facility scan information, the facility image information, the facility sound information, the facility vibration information, the facility vibration information, and the facility temperature information by connecting with each of the OHT proximity sensor 15, the OHT camera sensor 16, the OHT sound detection sensor 17, the OHT vibration detection sensor 18, and the OHT temperature detection sensor 19 to transmit the stored facility scan information, the facility image information, the facility sound information, the facility vibration information, and the facility temperature information to the OCS 20. In this case, the OHT information management module unit 19a stores the facility scan information, the facility image information, the facility sound information, the facility vibration information, and facility temperature information for each facility installed in the semiconductor manufacturing line and transmits it to the OCS 20.

If the OHT 10 stops at an article inlet of the semiconductor manufacturing facility 1 to transfer the article to the semiconductor manufacturing facility 1, the OHT proximity sensor 15, the OHT camera sensor 16, the OHT sound detection sensor 17, the OHT vibration detection sensor 18, and the OHT temperature detection sensor 19 are driven to be controlled so the facility scan information, the facility image information, the facility sound information, the facility vibration information, and the facility temperature information of the semiconductor manufacturing facility 1 are transmitted to the OHT information management module unit 19a.

The OCS 20 communicates with the OHTs 10 operating in the semiconductor manufacturing facility 1 to set or monitor the origin information, the destination information, and the position information of the OHT 10 to manage the driving schedule of the OHT 10.

In addition, if the OHT 10 transports the article within the semiconductor manufacturing facility 1, the OCS 20 receives the article information and the upload/unload information, and monitors articles contents and articles movement details. In addition, the OCS 20 monitors all the driving conditions of the OHTs 10 in conjunction with the OHTs 10 and receives and monitors the state information on a battery status, a power status, and an overload status of the OHTs 10.

In addition, the OCS 20 receives the facility scan information, the facility image information, the facility sound information, the facility vibration information, and the facility temperature information for each of the semiconductor manufacturing facilities 1 which are output from the OHT information management module unit 19a through the OHT communication unit 14 to transmit to the state monitoring unit 50.

The mobile robot 30 is an autonomous driving apparatus such as an autonomous mobile robot (AMR) or an automated guided vehicle (AGV) which automatically transfers the article within the semiconductor manufacturing facility 1 and stores and manages the facility scan information, the facility image information, the facility sound information, the facility vibration information, and the facility temperature information of each semiconductor manufacturing facility 1.

In this embodiment, the mobile robot 30 includes a mobile robot main body 31, a wheel 32, a mobile robot driving unit 33, a mobile robot control unit 34, a mobile robot communication unit 35, a mobile robot proximity sensor 36, a mobile robot camera sensor 37, a mobile robot sound detection sensor 38, a mobile robot vibration detection sensor 39, a mobile robot temperature detection sensor 39a, a mobile robot information management module unit 39b, and a mobile robot inspection operation unit 39c.

The mobile robot main body 31 provides a region which combines a wheel 32, a mobile robot driving unit 33, a mobile robot control unit 34, a mobile robot communication unit 35, a mobile robot proximity sensor 36, a mobile robot camera sensor 37, a mobile robot sound detection sensor 38, a mobile robot vibration detection sensor 39, a mobile robot temperature detection sensor 39a, a mobile robot information management module unit 39b and a mobile robot inspection operation unit 39c and forms a structure which in various forms which transfers and loads the article within the semiconductor manufacturing facility 1.

The wheel 32 is coupled to a motor shaft of the mobile robot driving unit 33 coupled to the mobile robot main body 31 and moves the mobile robot main body 31 when the driving motor (not shown) moves in contact with the ground within the semiconductor manufacturing facility 1.

The mobile robot driving unit 33 includes a motor (not shown) and a motor driving circuit (not shown), and receives a control command according to an autonomous driving command of the mobile robot control unit 34 to drive the wheel 32 linked to the motor, thereby driving the mobile robot main body 31 through the autonomous driving path.

The mobile robot control unit 34 is a control apparatus which the mobile robot driving unit 33 according to a command of a preset program, and stores a mobile robot map (not shown) generated by the mobile robot proximity sensor 36 and controls the mobile robot driving unit 33 to avoid the pre-explored obstacle information of the stored mobile robot map and autonomously drive according to an autonomous driving algorithm until the set destination. In addition, the mobile robot control unit 34 communicates with the mobile robot control system 40 to receive the origin information, the destination information, and the article information, and transmits the command for transporting the article while autonomously driving based on the input origin information, the destination information and the article information to the mobile robot driving unit 33. In addition, mobile robot map is formed with the image information having the grid coordinate values for each pixel, and mobile robot map displays pre-explored travelable paths and non-driving regions such as walls and facilities.

The mobile robot communication unit 35 is an apparatus which communicates with the mobile robot control system 40, and uses short-range communication such as a wireless LAN (Wifi), a short-range mesh network (N:N, Ad-hoc), a Bluetooth, a Zigbee, and an IrDA, or uses long-range communication if necessary. The mobile robot communication unit 35 transmits the origin information, the destination information, and the article information from the mobile robot control system 40 to the mobile robot control unit 34, and transmits the position information and various state information to the mobile robot control system 40. In addition, the mobile robot communication unit 35 transmits the information acquired by the mobile robot information management module unit 39b to the mobile robot control system 40 in communication with the mobile robot information management module unit 39b. In addition, the mobile robot communication unit 35 transmits the facility scan information, the facility image information, the facility sound information, the facility vibration information, and the facility temperature information to the mobile robot control system 40 in conjunction with the mobile robot information management module unit 39b.

The mobile robot proximity sensor 36 is a sensor which detects the obstacle in the autonomous driving path through a distance detection, consists of a laser distance detection sensor such as a lidar sensor, and may consist of an ultrasonic displacement sensor or an optical displacement sensor if necessary, and is installed in the mobile robot main body 31. Here, if detecting the obstacle, the mobile robot proximity sensor 36 transmits the collision warning information to the mobile robot control unit 34, and the mobile robot control unit 34 which has received the collision warning alert information modifies the driving path to the destination set to avoid the obstacle and drives autonomously. In this case, if the obstacle information is generated, the mobile robot proximity sensor 36 for the mobile robot transmits position information on the obstacle to the mobile robot control system 40.

In addition, the mobile robot proximity sensor 36 is installed within the mobile robot main body 31 and measures the semiconductor manufacturing facility 1 to generate the facility scan information by scanning by an outer shape of the semiconductor manufacturing facility 1 and transmits the generated facility scan information to the mobile robot information management module unit 39b. Here, the facility scan information is an information obtained by forming the semiconductor manufacturing facility 1 on a three-dimensional coordinate through a distance value for each range. In this case, the facility scan information may be formed as an image information having a grid coordinate value for each pixel, and the pixel information of the pixel may be set differently according to a depth value of the sensed 2D region to actualize the 3D shape information.

The mobile robot camera sensor 37 consists of a 2D camera or a 3D sensing camera, and is installed in the mobile robot main body 31. If the mobile robot 30 moves, the mobile robot camera sensor 37 acquires the facility image information by imaging the semiconductor manufacturing facility 1 and transmits the acquired facility image information to the mobile robot information management module unit 39b.

The mobile robot sound detection sensor 38 is composed of a sensor which converts an analog sound into an electronic sound signal, such as a microphone, and is installed in the mobile robot main body 31. The mobile robot sound detection sensor 38 receives the facility sound information generated if the semiconductor manufacturing facility 1 is driven and transmits it to the mobile robot information management module unit 39b.

The mobile robot vibration detection sensor 39 is composed of a sensor capable of sensing the vibration like an acceleration sensor, and is installed in the mobile robot main body 31. The mobile robot vibration detection sensor 39 receives the facility vibration information generated if the semiconductor manufacturing facility 1 is driven and transmits it to the mobile robot information management module unit 39b for the mobile robot.

The mobile robot temperature detection sensor 39a consists of a sensor capable of detecting the temperature, such as a thermocouple sensor or an infrared sensor, and is installed in the mobile robot main body 31. The mobile robot temperature detection sensor 39a measures the facility temperature information if the semiconductor manufacturing facility 1 is driven, and transmits the measured temperature information to the mobile robot information management module unit 39b.

Here, the above-described state information such as the facility scan information, the facility image information, the facility sound information, the facility vibration information, and the facility temperature information may be obtained in a stopped state at a specific position of the pre-stored mobile robot map storied in the mobile robot 30. For example, if entering the semiconductor manufacturing facility 1, the mobile robot 30 may obtain the state information in a stopped state.

The mobile robot information management module unit 39b records and manages the facility scan information, the facility image information, the facility sound information, the facility vibration information, and the facility temperature information, which are a state information for each of semiconductor manufacturing facilities 1. The mobile robot information management module unit 39b receives the facility scan information, the facility image information, the facility vibration information, the facility vibration information, the facility vibration information, and facility temperature information. In this case, the mobile robot information management module unit 39b stores the facility scan information, the facility image information, the facility sound information, the facility vibration information, and the facility temperature information for each facility installed in the semiconductor manufacturing line and to transmit to the mobile robot control system 40.

If the mobile robot 30 stops at the article inlet of the semiconductor manufacturing facility 1 to transfer the article to the semiconductor manufacturing facility 1, the mobile robot proximity sensor 36, the mobile robot camera sensor 37, the mobile robot sound detection sensor 38, the mobile robot vibration detection sensor 39, and the mobile robot temperature detection sensor 39a are driven so the facility scan information, the facility image information, the facility sound information, the facility vibration information, and the facility temperature information are transmitted to the mobile robot information management module unit 39b.

The mobile robot control system 40 communicates with mobile robots 30 operating in the semiconductor manufacturing facility 1 to set or monitor the origin information, the destination information, and the position information of the mobile robots 30 to manage the driving schedule of the mobile robot 30.

In addition, the mobile robot control system 40 receives the article information and and the article load/unload information when mobile robots 30 transfers articles within the semiconductor manufacturing facility 1 and monitors the article information and the article moving details. In addition, the mobile robot control system 40 monitors all driving conditions of the mobile robots 30 and receives and monitors a state information on a battery status, a power status, and an overload status of the mobile robots 30.

In addition, if the position information for the obstacle information is input from each mobile robot 30, the mobile robot control system 40 generates an obstacle map (not shown) consisting of the position information for the obstacle and transmits the generated obstacle map to the mobile robot 30. Here, the obstacle map is formed in the form of an image including grid coordinates for each pixel, and the mobile robot 30, which receives the obstacle map, runs autonomously while avoiding obstacles in the obstacle map if there is an obstacle on the pre-explored path during the autonomous driving. In this way, since the mobile robot 30 drives while avoiding obstacles in the obstacle map, it is possible to prevent a bottleneck phenomenon between the mobile robots 30 in an abnormal congestion section. In addition, the obstacle map can be used for reference when installing a new semiconductor manufacturing facility 1 to select an optimal placement position.

In addition, the mobile robot control system 40 receives the facility scan information, the facility image information, the facility sound information, the facility vibration information, and the facility temperature information for each semiconductor manufacturing facility 1 output from the mobile robot information management module unit 39b through the mobile robot communication unit 35 to transmit to the state monitoring unit 50.

The state monitoring unit 50 includes an inspection information storage unit 51, an abnormality detection unit 52, a grade alarm unit 53, and a facility life prediction unit 54.

The inspection information storage unit 51 is a communication terminal apparatus such as a PC or a server which continuously receives and stores the facility scan information, the facility image information, the facility sound information, the facility vibration information, and the facility temperature information for each of the OCS 20, the mobile robot control system 40, and the semiconductor manufacturing facility 1. In this case, a facility name and an inspection date for each facility are stored if the facility scan information, the facility image information, the facility sound information, the facility vibration information, and the facility temperature information are stored. As such, the facility scan information, the facility image information, the facility sound information, the facility vibration information, and the facility temperature information are periodically recorded and stored as per day, month, and year.

The abnormality detection unit 52 communicates with the inspection information storage unit 51 and if the facility scan information, the facility image information, the facility sound information, the facility vibration information, and the facility temperature information are input, detects cases in which there are changes in each of the input facility scan information, the facility image information, the facility sound information, the facility vibration information, and the facility temperature information from pre-stored values.

More specifically, with respect to the abnormality detection unit 52 detecting a change of the facility scan information, if the facility scan information of the semiconductor manufacturing facility 1 is input, it is detected that a position of the semiconductor manufacturing facility 1 has changed if grid coordinates of an outermost shape of the semiconductor manufacturing facility are changed from grid coordinates of a predetermined facility scan information.

In addition, with respect to the abnormality detection unit 52 detecting a change of the facility image information, if the facility image information of the semiconductor manufacturing facility 1 is input, it is detected that a shape of the semiconductor manufacturing facility 1 is changed if pixel values of the pre-stored facility image information of the semiconductor manufacturing facility 1 has a difference from the pixel values of the pixel values of the input facility image information.

Also, with respect to the abnormality detection unit 52 detecting a change of the facility sound information, if the facility sound information of the semiconductor manufacturing facility 1 is input, a change is detected by comparing a pre-stored frequency band of the facility sound information and a frequency band of an input facility sound information.

Also, with respect to the abnormality detection unit 52 detecting a change of the facility vibration information, if the facility vibration information of the semiconductor manufacturing facility 1 is input, a change is detected by comparing a pre-stored frequency band of the facility vibration information and a frequency band of an input facility vibration information.

In addition, with respect to the abnormality detection unit 52 detecting a change of the facility temperature information, if the facility temperature information of the semiconductor manufacturing facility 1 is input, a difference in a pre-stored facility temperature information is detected.

Meanwhile, the OHT inspection operation unit 19b of the OHT 10 and the mobile robot inspection operation unit 39c of the mobile robot 30 can detect abnormalities in the semiconductor manufacturing facility 1 while loading and unloading the article, and may be driven only for an inspection of the semiconductor manufacturing facility 1 while not loading/unloading the article.

If the abnormality detection unit 52 detects changes in each of the facility scan information, the facility image information, the facility sound information, the facility vibration information, and the facility temperature information, it determines into grades according to a change rate in the intensity or range and generates the alarm information accordingly. For example, if the change value for the facility scan information, the facility image information, the facility sound information, the facility vibration information, and the facility temperature information is within a reference error range, it can be determined as a normal grade, if the change value exceeds the reference error range but does not exceed the pre-set critical range it can be determined as an inspection grade, and if the change value exceeds the reference error range and exceeds the pre-set critical range it can be determined as a replacement grade. In this case, the alarm information is displayed on the display panel unit to be visually seen by an operator monitoring the state monitoring unit 50. Therefore, the operator can check the normal grade, the inspection grade, and the replacement grade of the semiconductor manufacturing facility 1 through the alarm information, and if the inspection grade and replacement grade are generated, the inspection and replacement work can be carried out.

In this case, the alarm information for the inspection grade and the replacement grade may be generated while being divided into a facility position inspection alarm for notifying that a position of the semiconductor manufacturing facility 1 is changed by a change of the facility scan information, a facility shape inspection alarm for notifying that a shape of the semiconductor manufacturing facility 1 is changed by a change of the facility image information, a driving sound inspection alarm for notifying that a driving sound of the semiconductor manufacturing facility 1 is changed by change of the facility sound information, a facility vibration inspection alarm for notifying that a vibration of the semiconductor manufacturing facility 1 has changed by a change of the facility vibration information, and a facility temperature inspection alarm for notifying that a temperature of the semiconductor manufacturing facility 1 has changed by a change of the facility temperature information.

The facility life prediction unit 54 monitors whether the intensity or range of each of the facility scan information, the facility image information, the facility sound information, the facility vibration information, and the facility temperature information of the semiconductor manufacturing facility 1 continuously increases for a preset period of time such as by day, month, or year in conjunction with the abnormality detection unit 52. If there is a continuous increase in a change rate of each of the facility scan information, the facility image information, the facility sound information, the facility vibration information, and the facility temperature information of the semiconductor manufacturing facility 1, a time for an increased inclining value to reach a critical point is estimated and calculated, and the estimated and calculated time is displayed as the time at which an error occurs in the semiconductor manufacturing facility 1. Therefore, the manager can determine a timing of maintenance work and replacement time according to the remaining life in advance through a predicted failure time of the semiconductor manufacturing facility 1, so that the semiconductor manufacturing facility 1 can take measures before an expected failure of the operation occurs due to aging.

Hereinafter, a transfer robot system driving method according to an embodiment of the inventive concept as described above will be described.

FIG. 6 is a flowchart of the transfer robot system driving method according to an embodiment of the inventive concept.

Referring further to FIG. 6, the transfer robot system driving method according to an embodiment of the inventive concept includes a driving step S10, an information acquisition step S20, an information storage step S30, an information comparison step S40, a grade notification step S50, and a life prediction step S60.

In the driving step S10, the OHT 10, which is an autonomous driving apparatus, is autonomously driven on the rail 2, and the mobile robot 30 is autonomously driven on a pre-explored path.

In the information acquisition step S20, if the OHT 10 which was autonomously driving stops at the semiconductor manufacturing facility 1 to load/unload the article, the OHT inspection operation unit 19b executes the OHT information management module unit 19a to transmit the facility scan information, the facility image information, the facility sound information, the facility vibration information, and the facility temperature information to the mobile robot control system 40. In addition, in the information acquisition step S20, if the mobile robot 30 which has autonomously driving stops at the semiconductor manufacturing facility 1 to load/unload the article, the mobile robot inspection operation unit 39c operates the mobile robot information management module unit 39b to transmit the facility scan information, the facility image information, the facility sound information, the facility vibration information, and the facility temperature information to the OCS 20.

In the information storage step S30, the state monitoring unit 50 receives and stores the facility scan information, the facility image information, the facility sound information, the facility vibration information, and the facility temperature information for each semiconductor manufacturing facility 1 in conjunction with the mobile robot control system 40 and the OCS 20.

In this case, the information storage step S30 is performed every time the OHT 10 and the mobile robot 30 enters the semiconductor manufacturing facility 1, and the facility scan information, the facility image information, the facility sound information, the facility vibration information, and the facility temperature information can be selectively stored according to the characteristics or process requirements of the semiconductor manufacturing facility 1.

In the information comparison step S40, the abnormality detection unit 52 of the state monitoring unit 50 compares the pre-stored facility scan information, the facility image information, the facility sound information, the facility vibration information, and the facility temperature information and the newly input facility scan information, the facility image information, the facility sound information, the facility vibration information, and the facility temperature information to comparatively determine whether a change has occurred in the pre-stored value.

In more detail, with respect to the determining process of whether a change has occurred in the facility scan information in the information comparison step S40, if the facility scan information is input in the information comparison step S40, the abnormality detection unit 52 determines whether the grid coordinates of an outermost shape of the semiconductor manufacturing facility changes from the grid coordinates of a pre-stored facility scan information.

In addition, with respect to the determining process of whether a change has occurred in the facility image information in the information comparison step S40, the abnormality detection unit 52 compares the pixel values of the pre-stored facility image information with the pixel values of the input facility image information of the semiconductor manufacturing facility 1 to detect changes in a shape of the semiconductor manufacturing facility 1.

Also, with respect to the determining process of whether a change has occurred in the facility sound information in the information comparison step S40, if the facility sound information which is generated due to an operation of the semiconductor manufacturing facility 1 is input, the abnormality detection unit 52 compares a frequency band of the pre-stored facility sound information with a frequency band of the input facility sound information to detect a change and to detect a driving sound change of the semiconductor manufacturing facility 1.

In addition, with respect to the determining process of whether a change has occurred in the facility vibration information in the information comparison step S40, if the facility vibration information which is generated due to an operation of the semiconductor manufacturing facility 1 is input, the abnormality detection unit 52 compares a frequency band of the pre-stored facility vibration information with a frequency band of the input facility vibration information to detect a vibration change and to detect a vibration change of the semiconductor manufacturing facility 1.

In addition, with respect to the determining process of whether a change has occurred in the facility temperature information in the information comparison step S40, if the facility temperature information which is generated due to an operation of the semiconductor manufacturing facility 1 is input, the abnormality detection unit 52 compares and determines whether a change has occurred in the pre-stored facility temperature information to detect the temperature change of the semiconductor manufacturing facility 1.

In the grade notification step S50, if the abnormality detection unit 52 detects changes in each of the facility scan information, the facility image information, the facility sound information, the facility vibration information, and the facility temperature information, the grade alarm unit 53 determines a normal grade, an inspection grade, and a replacement grade accordingly according to an intensity and a range and generates an alarm information accordingly. In this case, since the alarm information is displayed on the display panel unit as described above, the operator can check the normal grade, the inspection grade, and the replacement grade for the semiconductor manufacturing facility 1.

In addition, the alarm information generated by the grade alarm unit 53 in the grade notification step S50 further generates a facility position inspection alarm which notifies if a position of the semiconductor manufacturing facility 1 has changed due to a change in the facility scan information, a facility shape inspection alarm which notifies if a shape of the semiconductor manufacturing facility 1 has changed due to a change in the facility image information, a driving sound inspection alarm which notifies if a driving sound of the semiconductor manufacturing facility 1 has changed due to a change in the facility sound information, a facility vibration inspection alarm which notifies if a vibration of the semiconductor manufacturing facility 1 has changed due to a change in the facility vibration information, and a facility temperature inspection alarm which notifies if a temperature of the semiconductor manufacturing facility 1 has changed to a change of the facility temperature information, aside from an alarm of the inspection grade and the replacement grade.

In the life prediction step S60, the facility life prediction unit 54 communicates with the abnormality detection unit 52 to monitor whether the intensity or range of each of the facility scan information, the facility image information, the facility sound information, the facility vibration information, and the facility temperature information of the semiconductor manufacturing facility 1 increases for a certain period of time such as a day, a month, or a year. If a change value of each of the facility scan information, the facility image information, the facility sound information, the facility vibration information, and the facility temperature information of the semiconductor manufacturing facility 1 continue to increase, a time at which an error of semiconductor manufacturing facility 1 occurs is estimated and displayed by calculating a time until which an increasing inclining value reaches a threshold. Therefore, the operator can determine in advance a timing of a maintenance work and a replacement time according to a remaining life due to the predicted error time of the semiconductor manufacturing facility 1, so that a plan can be made so the semiconductor manufacturing facility 1 does not stop operating due to aging.

The effects of the inventive concept are not limited to the above-mentioned effects, and the unmentioned effects can be clearly understood by those skilled in the art to which the inventive concept pertains from the specification and the accompanying drawings.

Although the preferred embodiment of the inventive concept has been illustrated and described until now, the inventive concept is not limited to the above-described specific embodiment, and it is noted that an ordinary person in the art, to which the inventive concept pertains, may be variously carry out the inventive concept without departing from the essence of the inventive concept claimed in the claims and the modifications should not be construed separately from the technical spirit or prospect of the inventive concept.

1. A transfer robot system comprising:
an autonomous driving apparatus which transfers an article which is required by semiconductor manufacturing facilities and which collects a state information of a semiconductor manufacturing facility by autonomously driving within a space at which the semiconductor manufacturing facilities are installed; and
a state monitoring unit connected with the autonomous driving apparatus to continuously be input with the state information of the semiconductor manufacturing facilities and for monitoring a change value of the state information.

2. The transfer robot system of claim 1, wherein the autonomous driving apparatus consists of at least one among an OHT and a mobile robot.

3. The transfer robot system of claim 1, wherein the autonomous driving apparatus further includes a proximity sensor which generates a facility scan information with respect to a shape of the semiconductor manufacturing facility into the state information.

4. The transfer robot system of claim 1, wherein the autonomous driving apparatus further includes a camera sensor which generates a facility image information of an image of the semiconductor manufacturing facility into the state information.

5. The transfer robot system of claim 1, wherein the autonomous driving apparatus further includes a sound detection sensor which generates a facility sound information of a sound of the semiconductor manufacturing facility into the state information.

6. The transfer robot system of claim 1, wherein the autonomous driving apparatus further includes a vibration detection sensor which generates a facility vibration information of a sound of the semiconductor manufacturing facility into the state information.

7. The transfer robot system of claim 1, wherein the autonomous driving apparatus further includes a temperature detection sensor which generates a facility temperature information of a temperature of the semiconductor manufacturing facility into the state information.

8. The transfer robot system of claim 1, wherein the state monitoring unit further includes an inspection information storage unit which stores a facility name of the semiconductor manufacturing facility and an inspection time every set cycle, together with the state information.

9. The transfer robot system of claim 8, wherein the state monitoring unit further includes an abnormality detection unit for determining whether the state information has a change from a pre-stored value, if the state information is input in communication with the inspection information storage unit.

10. The transfer robot system of claim 9, wherein the state monitoring unit further includes a facility life prediction unit for monitoring how much a change rate of an intensity or a range of the state information increases during a predetermined period, in communication with the abnormality detection unit.

11.-19. (canceled)

20. The transfer robot system comprising:
an autonomous driving apparatus which transfers an article to semiconductor manufacturing facilities by autonomously driving within a space at which the semiconductor manufacturing facilities are installed, which collects a state information of a semiconductor manufacturing facility, and which is configured of at least one among an OHT and a mobile robot; and
a state monitoring unit connected with the autonomous driving apparatus to continuously be input with the state information of the semiconductor manufacturing facilities and for monitoring a change value of the state information, and
wherein the transfer robot system further comprises a proximity sensor which generates a facility scan information a shape of the semiconductor manufacturing facility into the state information; a camera sensor which generates a facility image information of an image of the semiconductor manufacturing facility into the state information; a sound detection sensor which generates a facility sound information of a sound of the semiconductor manufacturing facility into the state information; a vibration detection sensor which generates a facility vibration information of a sound of the semiconductor manufacturing facility into the state information; and a temperature detection sensor which generates a facility temperature information of a temperature of the semiconductor manufacturing facility into the state information, and
wherein the transfer robot system further comprises an inspection information storage unit which stores a facility name of the semiconductor manufacturing facility and an inspection time every set cycle, together with the state information; an abnormality detection unit for determining whether the state information has a change from a pre-stored value, if the state information is input in communication with the inspection information storage unit; and a facility life prediction unit for monitoring how much a change rate of a intensity or a range of the state information increases during a predetermined period, in communication with the abnormality detection unit.
